(19) United States
(12) Patent Application Publication
(10) Pub. No.: US 2016/0274179 A1
(43) Pub. Date: Sep. 22, 2016

(54) THERMOSTATIC CONTROLLER AND CIRCUIT TESTER

(71) Applicant: Errol Barton, Tamarac, FL (US)

(72) Inventor: Errol Barton, Tamarac, FL (US)

(21) Appl. No.: 14/660,073

(22) Filed: Mar. 17, 2015

(51) Int. Cl. G01R 31/28

(52) U.S. Cl. CPC G01R 31/282

(57) ABSTRACT

A thermostatic controller and circuit tester that includes: a control surface; a slider knob on the control surface, where the slider knob initiates power for testing and use of the thermostatic controller; a reading indicator on the control surface, where the reading indicator indicates a related parameter being measured; a digital display, where the digital display displays a reading; a top surface, where the top surface includes a first opening and a second opening; a first retractable cable extending from the first opening; and a second retractable cable extending from the second opening. The related parameters may include at least AC voltage, DC voltage, resistance, capacitance and continuity. The thermostatic controller may include a top surface with a LED lamp. Preferably, the first retractable cable includes test leads and the second retractable cable includes test leads.

### BACKGROUND OF THE INVENTION

1. Field of Invention

The present invention relates to a device that is used by technicians for troubleshooting and determining issues related to HVAC systems.

2. Description of Related Art

Many times technicians must conduct various tests on systems within a building to determine and pinpoint problems or issues with the electrical wiring systems. Technicians normally may also be required to take tests for electrical current or electrical signal flow in various appliances. Further technicians commonly must review various types of wiring and cable connections in order to install further equipment, appliances or to resolve issues. The tests related to the various testing of electrical systems and wiring typically involve numerous devices and tools that are able to detect voltage, either AC or DC, resistance, capacitance or other electrical circuit issues. This diagnostic information is critical in helping the technician resolve problems, in particular problems involving air conditioning systems and relate control systems. Further many times the technician must operate in areas that require additional light in the form of a flashlight or other temporary lighting to view circuits or to assess hidden compartments. As a consequence, it would be advantageous to have a device that can be used for testing and checking electrical systems, which could perform multiple tasks for the technician.

### SUMMARY OF THE INVENTION

The present invention relates to a thermostatic controller and circuit tester that includes: a control surface; a slider knob on the control surface, where the slider knob initiates power for testing and use of the thermostatic controller; a reading indicator on the control surface, where the reading indicator indicates a related parameter being measured; a digital display, where the digital display displays a reading; a top surface, where the top surface includes a first opening and a second opening; a first retractable cable extending from the first opening; and a second retractable cable extending from the second opening. The related parameters may include at least AC voltage, DC voltage, resistance, capacitance and continuity. The thermostatic controller may include a top surface with a LED lamp. Preferably, the first retractable cable includes test leads and the second retractable cable includes test leads.

### BRIEF DESCRIPTION OF DRAWINGS

FIG. 1 depicts a perspective view of a thermostatic controller and circuit tester in accordance with the present invention.

FIG. 2 depicts a rear view of the thermostatic controller in accordance with the present invention.

FIG. 3 provides a partial interior view of the thermostatic controller in accordance with the present invention.

### DETAILED DESCRIPTION

The present invention relates to a thermostatic controller and circuit tester. The controller and circuit tester according to the present invention includes a substantially rectangular box with a top surface with a slider knob to identify and initiate the testing that is conducted. The thermostatic controller also includes testing leads with retractable cords and a digital display of the readings. LED lighting is also included on thermostatic controller to assist in lighting poorly lit areas.

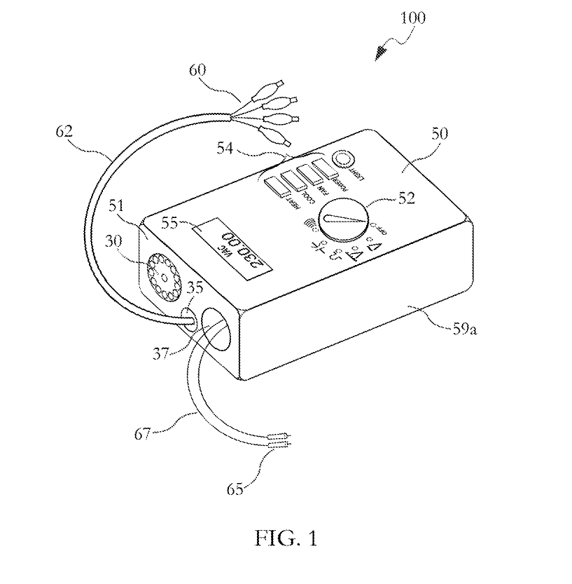

As shown in FIG. 1, a thermostatic controller 100 is depicted. This thermostatic controller 100 includes a control surface 50 thus depicts a slider knob 52. As shown, the slider knob 52 initiates power for testing and use of the thermostatic controller 100. Various parameters may be tested and in this particular embodiment parameters available for testing include AC and DC voltage, resistance, capacitance and continuity. A reading indicator 54 is provided that indicates the related parameter being measured. A digital display 55 is provided on the top surface 50 that displays the reading provided by the controller and circuit tester 100.

The controller 100 further includes a top surface 51. This top surface 51 includes a LED lamp 30 that provides illumination for the user. This illumination can be effective in providing light in dark hidden areas while using the controller and tester 100. Further along the top surface 51 is a first opening 35 that releases a cable 62 that includes testing leads 60. This cable 62 is retractable into the first opening 35. In addition to the first opening 35, a second opening 37 receives cable 67 that includes testing leads 65. The cable 67 is also retractable into the opening 37 provided.

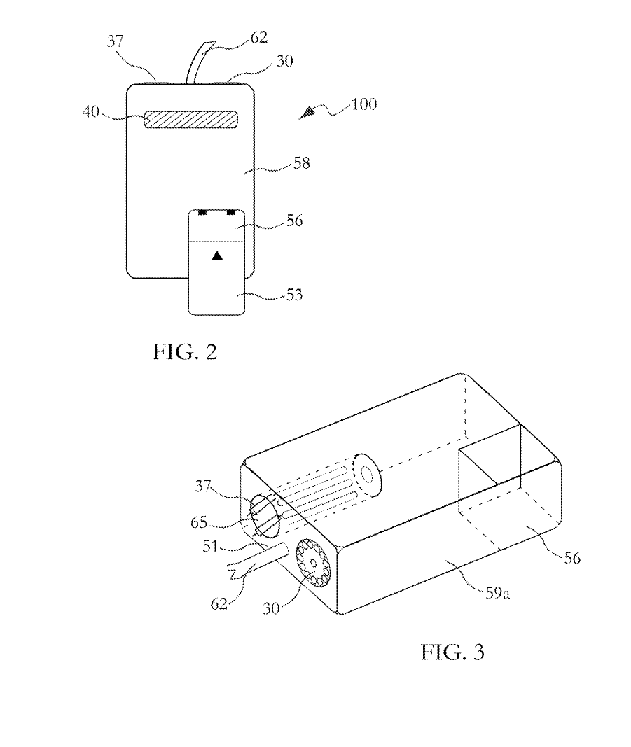

FIG. 2 provides a rearview of the controller and tester 100. A rear surface 58 includes a magnetic strip 40 that extends across the length of the rear surface 58. The magnetic strip 40 may be used to temporarily mount the testing device while connecting leads in the appropriate positions for testing purposes. A battery compartment 56 is also provided with battery cover 53. The controller tester 100 according to present invention is battery operated therefore a compartment is provided for the insertion of DC power for the controller.

FIG. 3 depicts a partial view of the interior of the controller tester 100 according to the present invention. As shown, the second opening 37 includes a cavity that receives the cable 67. Cable 62 extends from the opening 35. Further side 59a is shown on one side of a controller tester 100. The user of the present invention may attach the testing leads 60, 65 to particular wires for testing purposes. The particular test conducted maybe controlled by the sliding knob 52 with digital readout provided by display 55. This device provides a composite device that is capable of multiple functions and testing to assist the technician in conducting various tests. The instant invention has been shown and described in what it considers to be the most practical and preferred embodiments. It is recognized, however, that departures may be made there from within the scope of the invention and that obvious modifications will occur to a person skilled in the art.

What is claimed is:

1. A thermostatic controller and circuit tester comprising:
a. a control surface;
b. a slider knob on the control surface, where the slider knob initiates power for testing and use of the thermostatic controller;
c. a reading indicator on the control surface, where the reading indicator indicates a related parameter being measured;
d. a digital display, where the digital display displays a reading;
e. a top surface, where the top surface includes a first opening and a second opening;
f. a first retractable cable extending from the first opening; and
g. a second retractable cable extending from the second opening.

2. The thermostatic controller according to claim 1, where the related parameter includes at least AC voltage, DC voltage, resistance, capacitance and continuity.

3. The thermostatic controller according to claim 1 where the top surface includes a LED lamp.

4. The thermostatic controller according to claim 1, where the first retractable cable includes test leads.

5. The thermostatic controller according to claim 1, where the second retractable cable includes test leads.

6. The thermostatic controller according to claim 1, further including a rear surface, where the rear surface includes a magnetic strip extending across the length thereof.

7. The thermostatic controller according to claim 6, where the rear surface also includes a battery compartment with battery cover.
